(19) United States
(12) Patent Application Publication
(10) Pub. No.: US 2016/0290600 A1
(43) Pub. Date: Oct. 6, 2016

(54) MULTI-COLORED LED ARRAY ON A SINGLE SUBSTRATE

(71) Applicant: VERILY LIFE SCIENCES LLC, Mountain View, CA (US)

(72) Inventors: William J. Biederman, Fox Island, WA (US); James Etzkorn, Mountain View, CA (US)

(21) Appl. No.: 14/678,639

(22) Filed: Apr. 3, 2015

(51) Int. Cl. F21V 9/08; F21V 9/16; G02C 11/04; H01L 27/15; H01L 33/50

(52) U.S. Cl. CPC F21V 9/08; H01L 27/15; H01L 33/502; G02C 11/04; F21V 9/16; F21W 2111/10

(57) ABSTRACT

A multi-colored display includes a semiconductor substrate layer, a first light emitting diode (“LED”) integrated onto the semiconductor substrate layer to natively emit pump light having a first color, a second LED integrated onto the semiconductor substrate layer to natively emit the pump light having the first color, and a first wavelength conversion layer disposed over an emission aperture of the second LED to convert the pump light natively emitted from the second LED to first output light having a second color different from the first color of the pump light. The first wavelength conversion layer includes a first matrix of quantum dots. The first and second LEDs are integrated into a single semiconductor die.

### TECHNICAL FIELD

This disclosure relates generally to light emitting diodes (“LEDs”), and in particular but not exclusively, relates to multi-colored LED sources.

### BACKGROUND INFORMATION

A light emitting diode (“LED”) is a semiconductor device that emits light from a p-n junction when a voltage is applied across the p-n junction causing electrons and hole to recombine. The color of the light emitted from the p-n junction of an LED is determined by the energy level of the photons emitted during recombination. The Planck-Einstein relation for a photon expresses the relationship between energy level and wavelength (color) of a photon. The Planck-Einstein relation states:

$$E = \frac{hc}{λ} ,$$

where E represents energy, h is Planck's constant, c is the speed of light, and λ is the wavelength (color). The energy level E of the photons emitted from the p-n junction is dependent upon the band gap energy of the junction, which in turn is dependent upon the p and n semiconductor materials used to form either side of the junction. Typical LED semiconductor materials include GaAs, GaN, etc.

Accordingly, the p-n junction of an LED having two defined semiconductor materials releases light having a defined wavelength or color signature. Typically, if multi-color LED lighting is desired, then different materials are brought together to form different band gap energies. Conventionally, this has been accomplished using different manufacturing processes to fabricate distinct p-n junctions on distinct LED semiconductor dice. These semiconductor dice are then combined into a single package to form a multi-color LED display device. Such devices are relatively large compared to the individual p-n junction diodes due to the requirement for external connections (e.g., wire bonds) between the distinct semiconductor devices.

Other multi-color LED displays have relied upon white light sources and absorptive filters. However, these multi-color devices are also large. The white light LEDs often use phosphorus layers and the absorptive filters are typically on the order of 100's of microns in thickness. Again, these additional elements are relatively large compared to the p-n junction of the LED itself.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. The drawings are not necessarily to scale, emphasis instead being placed upon illustrating the principles being described.

FIG. 1A is a plan view illustration of a multi-color display fabricated of three light emitting diodes (“LEDs”) integrated into a single semiconductor die, in accordance with an embodiment of the disclosure.

FIG. 1B is a side view illustration of the multi-color display fabricated of three LEDs integrated into the single semiconductor die, in accordance with an embodiment of the disclosure.

FIG. 2 is a plan view illustration of a multi-color display having a color pixel array formed from LEDs all integrated into a single semiconductor die, in accordance with an embodiment of the disclosure.

FIGS. 3A and 3B illustrate different views of a contact lens that includes a multi-color LED display embedded within the contact lens, in accordance with an embodiment of the disclosure.

### DETAILED DESCRIPTION

Embodiments of an apparatus and method of operation for a multi-colored display implemented using light emitting diodes (“LEDs”) integrated into a single semiconductor die are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

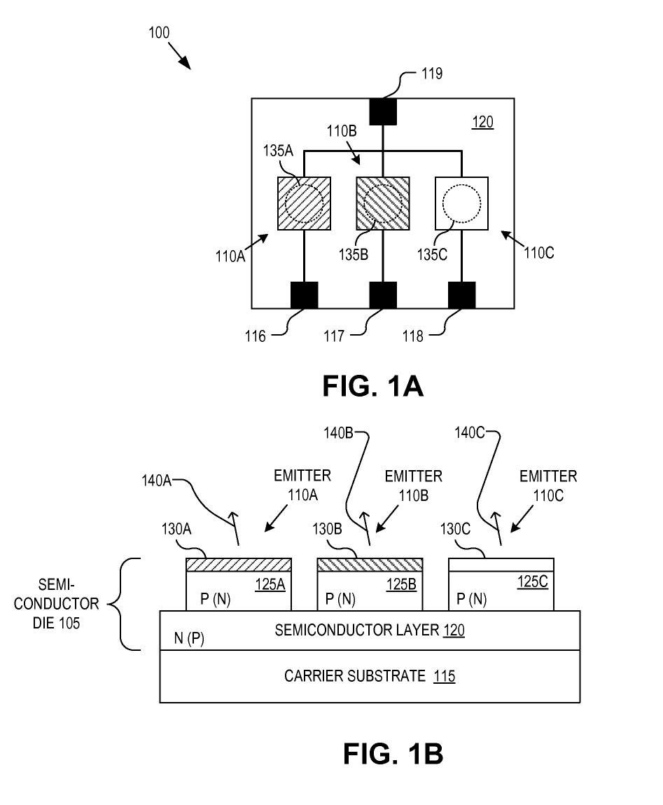

FIGS. 1A and 1B are illustrations of a multi-color display 100 including three LEDs integrated into a single semiconductor die, in accordance with an embodiment of the disclosure. FIG. 1A is a plan view illustration of multi-color display 100 while FIG. 1B is a side view illustration of the same. The illustrated embodiment of multi-color display 100 includes a semiconductor die 105 having multi-color LED emitters 110A, 110B, and 110C (collectively LED emitters 110) integrated onto semiconductor die 105, which in turn is disposed on a carrier substrate 115. Semiconductor die 105 further includes four contact terminals connected to drive the emitters 110A-C including color terminals 116, 117, 118, and a common terminal 119. Accordingly, the illustrated embodiment of multi-color display 100 is a tri-color, four terminal display.

The illustrated embodiment of emitter 110A includes a portion of the shared or common semiconductor layer 120, a semiconductor layer 125A, and a wavelength conversion layer 130A disposed over an emission aperture 135A. The illustrated embodiment of emitter 110B includes a portion of the shared or common semiconductor layer 120, a semiconductor layer 125B, and a wavelength conversion layer 130B disposed over an emission aperture 135B. The illustrated embodiment of emitter 110C includes a portion of the shared or common semiconductor layer 120, a semiconductor layer 125C, and a wavelength conversion layer 130C disposed over an emission aperture 135C. In some embodiment, wavelength conversion layer 130C may be omitted or substituted for one or more non-wavelength conversion materials such as a diffusive material, a clear protecting layer, an anti-reflective layer, or otherwise. Collectively, wavelength conversion layers 130A-C are referred to as wavelength conversion layers 130.

In the illustrated embodiment, LED emitters 110 are all fabricated of the same constituent semiconductor materials, using the same manufacturing process, and share a common semiconductor layer 120 all integrated onto the single semiconductor die 105. In fact, the common semiconductor layer 120 operates as either a common anode or cathode to LED emitters 110 depending upon its conductivity type (e.g., n-type or p-type), while semiconductor layers 125A-C form the complementary anode/cathode for each LED emitter 110. LED emitters 110 may be fabricated using a variety of LED manufacturing processes using different semiconductor materials (e.g., III-V semiconductor materials, II-VI semiconductor materials, GaAs, GaN, silicon, etc.). In the illustrated embodiment, semiconductor die 105 is disposed on a carrier substrate 115 (e.g., sapphire) as a mechanical base. Accordingly, shared semiconductor layer 120 forms a shared half of the p-n junctions of LED emitters 110 while semiconductor layers 125A-C form the other half of the p-n junctions.

Although LED emitters 110 and their p-n junctions are fabricated using identical materials, LED emitters 110 may be fabricated to have different sizes, shapes, or layout orientations to achieve different desired effects (e.g., different brightness between the respective LED emitters 110). However, because LED emitters 110 are all made of the same materials and manufacturing process their p-n junctions natively output pump light having the same wavelength as each other. For example, in one embodiment, the p-n junction of each LED emitter 110 outputs blue light. In yet other embodiments, the p-n junctions could be fabricated to output other colors such as ultra-violate light, or otherwise. By manufacturing LED emitters 110 using the same materials and process, they can be integrated on the single semi-conductor die 105, which facilitates a compact, inexpensive, and power efficient multi-color display 100.

The multi-color output light is achieved from LED emitters 110 by way of wavelength conversion layers 130, which are disposed (e.g., coated) over emission apertures 135 of LED emitters 110. The illustrated embodiment of LED emitters 110 are vertical surface emission LEDs that emit their pump light into wavelength conversion layer 130 through their respective emission apertures 135. Wavelength conversion layers 130 are relative thin layers (e.g., 10's of um thick or even less than 10 um thick) when compared to phosphorus layers or absorptive color filter layers, which are often 100's of um thick. This enables thin, compact multi-color displays.

Wavelength conversion layers 130 may be fabricated using a colloidal suspension of quantum dots. The dispersed phase (quantum dots) are nano structures that exhibit quantum mechanical properties by spatially confining excitons. In particular, quantum dots can be formed to absorb photons at one wavelength and reemit photons at another wavelength. In this manner, quantum dots operate as wavelength conversion elements that absorb the native pump light output from the p-n junctions of LED emitters 110 and reemit output light of different colors. The wavelength of the reemitted light (output light 140) is selected by the design of the quantum dots within the wavelength conversion layers 130. For example, both the physical size and material choices selected for the quantum dots affect the available quantum mechanical energy states in which charge particles may exist and therefore control the wavelength of output light 140. Via appropriate manipulation of the quantum dot structures and materials, as is known in the art, wavelength conversion layers 130 can be designed to emit output light 140 with a specified color.

In various embodiments, wavelength conversion layers 130 are fabricated by suspending quantum dots within a light transmissive polymer. In one embodiment, the polymer may be a photo-patternable polymer (e.g., photoresist) that facilitates photolithographic patterning of wavelength conversion layers 130. Multiple iteration of coating (e.g., spin coating or spray coating) and patterning may be performed to achieve the multiple different colors on semiconductor die 105. In yet other embodiments, soft lithography may be used to dispose the different wavelength conversion layers 130 onto LED emitters 110. For example, the two or three different color colloid suspension layers of quantum dots may be fabricated separately. Then, soft lithographic techniques may be used to stamp out instances of wavelength conversion layers 130 from the different color colloidal suspensions and the instances transferred onto their respective semiconductor layers 125A-C. Heat and/or pressure is then used to cause the transferred wavelength conversion layer 130 to adhere over the given LED emitter 110.

The illustrated embodiment of multi-color display 100 includes three LED emitters 130. Each LED emitter 103 is designed to emit light 140 of a different color, such that multi-color display 100 outputs tri-color display light. For example, wavelength conversion layer 135A may include a quantum dot suspension that absorbs blue pump light and reemits green output light 140A, wavelength conversion layer 135B may include a quantum dot suspension that absorbs blue pump light and reemits red output light 140B, while wavelength conversion layer 140C may be omitted to allow the blue pump light to be directly emitted as blue output light 140C. In other embodiments, the pump light natively output from the p-n junctions of LED emitters 110 may be other colors (e.g., ultra violate, etc.). In such embodiments, wavelength conversion layer 135C may include a quantum dot suspension that absorbs the pump light and reemits blue output light 140C. Of course, other tri-color combinations (color spaces) may be implemented including cyan, yellow, and magenta, or otherwise.

The tri-color display 100 illustrated in FIGS. 1A and 1B is a four terminal device including color terminals 116, 117, 118, and a common terminal 119. Terminals 116-119 may be implemented as bonding pads with signal traces that route to LED emitters 110. Common terminal 119 operates as a common electrode (e.g., ground), while the color terminals 116-118 are each coupled to activate a corresponding one of LED emitters 110. In one embodiment, common terminal 119 is connected to the shared semiconductor layer 120, while color terminals 116-118 couple to respective semiconductor layers 125A-125C. By appropriate application of voltage via terminals 116-119, each LED emitter 110 can be independently activated and controlled. Accordingly, terminals 116-119 are used to selectively and appropriately bias the p-n junctions of the individual LED emitters 110 to stimulate emission. The interface of multi-color display 100 requires few terminal connections, which eases fabrication.

FIGS. 1A and 1B illustrate a tri-color, four terminal multi-color display. However, it should be appreciated that other embodiments may include a two color, three terminal display, or even greater than three color display. In yet other embodiments, multi-color display 100 may be implemented as a tri-color display, but have more than just three LED emitters 110 to provide a display capable of displaying multi-pixel color images.

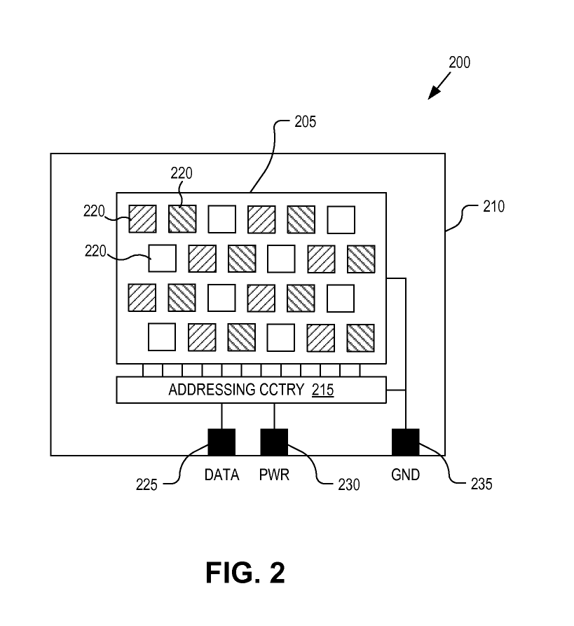

FIG. 2 is a plan view illustration of a multi-color display 200 having a color pixel array 205 formed from LEDs all integrated into a single semiconductor die 210, in accordance with an embodiment of the disclosure. When the number of LED emitters 220 within color pixel array 205 passes a threshold number, it becomes impractical to have an independent contact pad or terminal for each LED emitter 220. Accordingly, the illustrated embodiment of multi-color display 200 further includes addressing circuitry 215 for driving the large number of color LED emitters (pixels) 220 disposed within color pixel array 205. LED emitters 220 can be fabricated in the same manner as LED emitters 110 in FIGS. 1A and 1B (e.g., be integrated into a shared semiconductor layer on a single semiconductor die), but are activated via addressing circuitry 215. In one embodiment, addressing circuitry 215 is coupled to receive a serial bit-stream from a data terminal 225 and decodes the bit-stream to display an image on the LED color pixel array 205. Although FIG. 2 illustrates multi-color display 200 as including just three terminals: data terminal 225, power terminal 230, and ground terminal 235, in other embodiments additional terminals may be added for the operation of addressing circuitry 215.

As mentioned above, by integrating LED emitters onto a single semiconductor die and using quantum dot overlays, thin, compact, low cost, and power efficient displays can be created. The multi-color displays described above are well suited for display applications requiring one or more of these benefits. One such category is body wearable displays; however, applications are not limited in this regard.

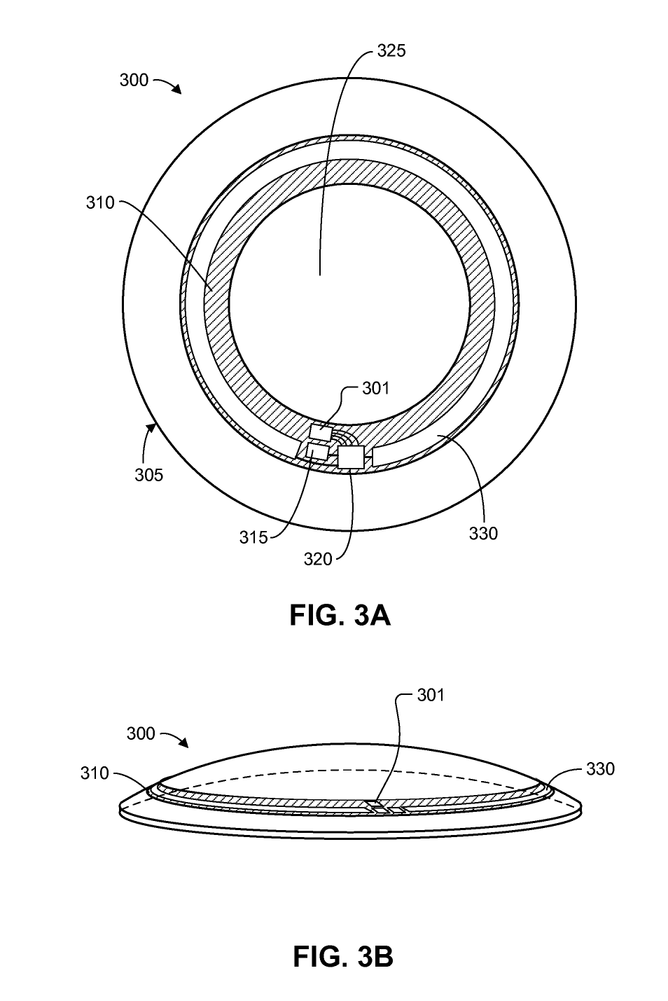

FIGS. 3A and 3B illustrate different views of a contact lens 300 that includes a multi-color LED display 301 embedded within the contact lens, in accordance with an embodiment of the disclosure. The illustrated embodiment of contact lens 300 includes display 301, an enclosure material 305, a substrate 310, a power supply 315, a controller 320, a center region 325, and an antenna 330. It should be appreciated that FIGS. 3A and 3B are not necessarily drawn to scale, but have been illustrated for purposes of explanation only in describing the arrangement of the example contact lens 300. Furthermore, contact lens 300 may be implemented as a smart contact lens including other components and circuitry for performing additional functions including glucose monitoring, auto-accommodation, etc.

Multi-color LED display 301 may be implemented using multi-color displays 100 or 200 disclosed above. Since display 301 can be fabricated, in some embodiments, to have a thickness of less than 10 um, it can be embedded within the envelope of a smart contact lens without wearer discomfort. Multi-color LED display 301 provides a multi-colored visual indicator to a wearer of contact lens 300, which can provide the wearer system status information, warnings, reminders, or other visual information relevant to the operation of contact lens 300. For example, display 301 may flash different colors to indicate to the wearer whether their blood glucose has deviated outside an acceptable range and even by how much or whether it is high or low. In the three emitter embodiment illustrated in FIGS. 1A and 1B, only four circuit traces need be routed to display 301 for its operation.

The illustrated embodiment of substrate 330 is a ring structure that encircles central region 325 to provide the user with unobstructed central vision. In one embodiment, substrate 310 is transparent or semitransparent and display 301 is mounted on the outside of substrate 310 to emit light through substrate 330 to the wearer's eye. In other embodiments, display 301 may be mounted on the backside of substrate 310 facing the wearer's eye. Substrate 310, display 301, power supply 315, controller 320, and an antenna 330 are all disposed within enclosure material 305. Enclosure material 210 is a biocompatible material similar to those employed to form vision correction and/or cosmetic contact lenses in optometry, such as a polymeric material, polyethylene terephthalate (“PET”), polymethyl methacrylate (“PMMA”), polyhydroxyethylmethacrylate (“polyHEMA”), a hydrogel, silicon based polymers (e.g., fluoro-silicon acrylate) combinations of these, or otherwise. Antenna 330 may be implemented as a backscatter antenna to provide low power wireless communication and even wireless inductive charging of power supply 315, in some embodiments.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A multi-colored display, comprising:
a semiconductor layer;
a first emitter including a first light emitting diode (“LED”) integrated onto the semiconductor layer, the first emitter configured to output first light having a first wavelength;
a second emitter including a second LED integrated onto the semiconductor layer, the second emitter configured to output second light having a second wavelength different from the first wavelength; and
a third emitter including a third LED integrated onto the semiconductor layer, the third emitter configured to output third light having a third wavelength different from the first and second wavelengths,
wherein the first, second, and third LEDs are integrated into a single semiconductor die that includes the semiconductor layer.

2. The multi-colored display of claim 1,
wherein the first emitter includes a first quantum dot layer disposed over a first emission aperture of the first LED to convert pump light natively output from the first LED having a pump wavelength to the first light having the first wavelength,
wherein the second emitter includes a second quantum dot layer disposed over a second emission aperture of the second LED to convert the pump light natively output from the second LED having the pump wavelength to the second light having the second wavelength,
wherein the first and second wavelengths are different from each other and different from the pump wavelength.

3. The multi-colored display of claim 2, wherein the third emitter does not include a layer of quantum dots overlaying a third aperture of the third LED and wherein the third light is the pump light output natively from the third LED.

4. The multi-colored display of claim 2, wherein the third emitter includes a third quantum dot layer disposed over a third emission aperture of the third LED to convert the pump light natively output from the third LED having the pump wavelength to the third light having the third wavelength.

5. The multi-colored display of claim 2, further comprising:
a first drive terminal electrically coupled to drive the first LED of the first emitter to output the first light;
a second drive terminal electrically coupled to drive the second LED of the second emitter to output the second light;
a third drive terminal electrically coupled to drive the third LED of the third emitter to output the third light; and
a common terminal electrically coupled to each of the first, second, and third LEDs to provide a common ground,
wherein the multi-colored display has only four terminals for driving the first, second, and third emitters with three different colors.

6. The multi-colored display of claim 1, wherein the single semiconductor die is disposed within a contact lens and wherein the multi-colored display is configured to provide a multi-colored visual indicator to a wearer of the contact lens.

7. A multi-colored display, comprising:
a semiconductor substrate layer;
a first light emitting diode (“LED”) integrated onto the semiconductor substrate layer to natively emit pump light having a first color;
a second LED integrated onto the semiconductor substrate layer to natively emit the pump light having the first color; and
a first wavelength conversion layer disposed over an emission aperture of the second LED to convert the pump light natively emitted from the second LED to first output light having a second color different from the first color of the pump light, wherein the first wavelength conversion layer includes a first matrix of quantum dots,
wherein the first and second LEDs are integrated into a single semiconductor die.

8. The multi-colored display of claim 7, wherein the first and second LEDs are fabricated on the single semiconductor die using a single manufacturing process for both the first and second LEDs.

9. The multi-colored display of claim 7, wherein the first and second LEDs are both fabricated of identical p and n semiconductor materials.

10. The multi-colored display of claim 7, further comprising:
a third LED integrated onto the semiconductor substrate layer to natively emit the pump light having the first color; and
a second wavelength conversion layer disposed over an emission aperture of the third LED to convert the pump light natively emitted from the third LED to second output light having a third color different from the first and second colors, wherein the second wavelength conversion layer includes a second matrix of quantum dots disposed,
wherein the first, second, and third LEDs are integrated into the single semiconductor die.

11. The multi-colored display of claim 10, further comprising:
a first drive terminal electrically coupled to the first LED to drive the first LED to generate the pump light;
a second drive terminal electrically coupled to the second LED to drive the second LED to generate the pump light;
a third drive terminal electrically coupled to the third LED to drive the third LED to generate the pump light; and
a common terminal electrically coupled to each of the first, second, and third LEDs to provide a common ground,
wherein the multi-colored display has only four terminals for driving the first, second, and third LEDs.

12. The multi-colored display of claim 10, wherein the first, second, and third LEDs comprise blue LEDs and the first color is blue.

13. The multi-colored display of claim 12, wherein an emission aperture of the first LED is not overlaid with a matrix of quantum dots and wherein the first LED outputs the pump light from the multi-colored display without conversion of the first color of the pump light.

14. The multi-colored display of claim 12, wherein the second color comprises red and the third color comprises green.

15. The multi-colored display of claim 10, wherein the pump light comprises white light.

16. The multi-colored display of claim 10, further comprising:
a third wavelength conversion layer disposed over an emission aperture of the first LED to convert the pump light natively emitted from the first LED to third output light having a fourth color different from the second and third colors, wherein the third wavelength conversion layer includes a third matrix of quantum dots.

17. The multi-colored display of claim 10, further comprising:
a plurality of first, second, and third LEDs forming a pixel array;
a plurality of first wavelength conversion layers disposed over the second LEDs;
a plurality of second wavelength conversion layers disposed over the third LEDs; and
addressing circuitry coupled to receive an image data stream and coupled to drive the pixel array with the image data stream.

18. The multi-colored display of claim 7, wherein the single semiconductor die is disposed within a contact lens and wherein the multi-colored display is configured to provide a multi-colored visual indicator to a wearer of the contact lens.

19. The multi-colored display of claim 7, wherein the first and second LEDs share either a common anode semiconductor layer or a common cathode semiconductor layer.

20. A method of generating multi-colored light, comprising:
generating pump light having a first color from a plurality of light emitting diodes (“LEDs”) integrated into a single semiconductor die, wherein all of the LEDs are fabricated of identical p and n semiconductor materials;
converting the pump light output from a first LED to first output light having a second color different from the first color of the pump light using a first layer of quantum dots coated over a first emission aperture of the first LED;
outputting the first output light having the second color from the first layer of quantum dots;
converting the pump light output from a second LED to second output light having a third color different from the first and second colors using a second layer of quantum dots coated over a second emission aperture of the second LED, wherein the second layer of quantum dots absorb the pump light and reemit the second output light; and
outputting the second output light having the third color from the second layer of quantum dots.

21. The method of claim 20, further comprising:
outputting the pump light from a third LED as third output light having the first color without converting a wavelength of the pump light.

22. The method of claim 21, wherein the first, second, and third LEDs are blue LEDs that natively emit the pump light as blue light.

23. The method of claim 22, wherein the first output light is comprises red light and the second output light comprises green light.

24. The method of claim 20, wherein the first, second, and third LEDs are different instances of identical LEDs integrated into a common semiconductor layer of the semiconductor die and wherein the plurality of LEDs are fabricated on the common semiconductor layer using a single manufacturing process for all of the plurality of LEDs.
